(19) United States
(12) Patent Application Publication
(10) Pub. No.: US 2008/0024116 A1
(43) Pub. Date: Jan. 31, 2008

(54) Coupling Electrode for Capacitive Voltage Tapping within the Insulating Body of a Bushing or of a Post Insulator

(75) Inventors: Clemens Albert, Goldbach (DE); Wilfried Albert, Gross Ostheim (DE); Stefan Hohmann, Petersberg (DE); Helmut Spack, Aschaffenburg (DE)

Correspondence Address: LERNER GREENBERG STEMER LLP, P O BOX 2480, HOLLYWOOD, FL, 33022-2480, US

(73) Assignee: Siemens Aktiengesellschaft, Munich (DE)

(21) Appl. No.: 11/632,603

(22) PCT Filed: Jul. 14, 2005
(86) PCT No.: PCT/EP05/53380

§ 371 Date: Jan. 16, 2007

(30) Foreign Application Priority Data
Jul. 16, 2004 (DE) 10 2004 035 176.7

(51) Int. Cl. G01R 1/06

(52) U.S. Cl. 324/149

(57) ABSTRACT

A coupling electrode for capacitive voltage tapping within an insulating body of a component which has at least one conductor section which is embedded in the insulating body and to which a high-voltage potential can be applied, having an electrode section which is composed of a semiconductive plastic, and having a connecting element which is electrically connected to the electrode section and is designed such that it can be passed out of the insulating body. A holder which is composed of a non-conductive material and, is connected to the electrode section and has the positioning means, which allow isolated mounting of the electrode section.

The invention relates to a coupling electrode for capacitive voltage tapping within an insulating body of a component which has at least one conductor section which is embedded in the insulating body and to which a high-voltage potential can be applied, having an electrode section which is composed of a semiconductive plastic, and having a connecting element which is electrically connected to the electrode section and is designed such that it can be removed from the insulating body.

The invention also relates to a component having at least one conductor section to which a high-voltage potential can be applied and having an insulating body which is made of insulating material and in which each conductor section is embedded.

A coupling electrode such as this and a component such as this are already known from EP 0 400 491 A2. The coupling electrode disclosed there has an annular electrode section composed of a semiconductive plastic. A connecting element in the form of a connecting pin is integrally formed on the electrode section such that an electrically conductive connection is formed between the connecting pin and the electrode section. The component disclosed there has an insulating body, in which said coupling electrode is embedded. In this case, the connecting element is passed out of the insulating body, so that the potential on the electrode section can be tapped off at the connecting element by means of expedient connecting plugs. In this case, the annular electrode section surrounds a conductor section, which likewise extends through the insulating body, with the conductor section and the electrode section being arranged coaxially with respect to one another. The described component is used as a so-called bushing for high-voltage and medium-voltage purposes. During operation, the conductor section has a high-voltage potential applied to it, with the coupling electrode being used as a capacitive divider element, across which a potential which is proportional to the high-voltage potential is produced and by means of which the voltage on the conductor section can be tracked. The already known coupling electrode and the already known component have the disadvantage that, during the production of the insulating body for the component, the coupling electrode must be positioned on the connecting element in a complex manner. Furthermore, such retention of the coupling electrode during the casting process is susceptible to faults, so that measurement inaccuracies can occur.

The invention is based on the object of providing a coupling electrode and a component of the type mentioned initially which costs little, while allowing accurate alignment of the coupling electrode within the cast insulating body.

The invention achieves this object by a holder which is composed of a non-conductive material, is connected to the electrode section and has the positioning means, which allow isolated mounting of the electrode section.

According to the invention, the coupling electrode has a non-conductive holder. According to the invention, because the holder is non-conductive, it is possible for the coupling electrode to be brought into contact by means of the positioning means of the holder with, for example, an area of the component which will be at ground potential during subsequent use, without this having any negative affect on the electrical characteristics of the coupling electrode. This results in the positioning of the coupling electrode and the formation of an electrical connecting point being separated, according to the invention.

The insulating body is expediently composed of cast resin. The chosen semiconductive plastic from which the electrode section is made and the cast resin have a similar coefficient of thermal expansion, so that this avoids mechanical stresses being produced within the insulating body when major temperature changes occur.

A connecting plug is expediently provided which is connected to a conductor and can be pushed onto the connecting element. This allows the coupling electrode to be detachably connected to other electronic appliances, for example protective appliances.

According to one expedient further development relating to this, sealing means are provided and are designed to hold the connecting plug in the insulating body. The sealing means are, for example, arranged in the insulating body of the component, before the insertion of the connecting plug. The connecting plug is then simply inserted subsequently into the component, and is pushed onto the sealing means in the process. The sealing means not only allow simple electrical connection of the coupling electrode but also electrical isolation of the connecting plug in the component. Furthermore, the sealing means prevent the ingress of moisture or other contamination. Within the scope of the invention, it is, of course, also possible for the sealing means to be attached to the connecting plug before this is inserted into the insulating body.

In one expedient further development in this context, the sealing means are composed of an elastomer. The elastomer is advantageously an insulating material. According to the invention, there is no need for the subsequent encapsulation of the connecting plug with sealing materials, as is known from the prior art. For example, the elastomer is an expedient silicone rubber or the like.

In one preferred further development of the invention, the sealing means can be latched in the insulating body of the component. Latching grooves, for example, are formed for this purpose in the insulating body, into which the sealing means are pressed during insertion of the connecting plug. By way of example, the latching grooves are located in a recess which is provided in the insulating body and into which the connecting element projects. The sealing means are sufficiently elastic that, on the one hand they allow them to enter the latching grooves and thus to engage behind them. On the other hand, the elasticity is chosen so that a sufficiently high retention force is provided in order to prevent the connecting plug from accidentally sliding out of the insulating body. By way of example, the sealing means are a single sealing element.

The semiconductive plastic advantageously contains polyphenylene sulfide and carbon fibers. This mixture ensures sufficiently high conductivity, with the coefficient of thermal expansion being very largely matched to that of the cast resin which is normally used for production of the insulating body. Mechanical stresses between the electrode section and the insulating body with resultant material fractures are prevented in this way. The semiconductive plastic is preferably composed only of the two constituents that have been mentioned, however, within the scope of this further development, it is also possible to use conventional additives, with the stated proportion of the carbon fibers always relating to the total weight of the electrode section.

According to one expedient further development in this context, the proportion of carbon fibers is between 15% by weight and 35% by weight. A carbon fiber proportion in this range has been found to be sufficient to provide the required conductivity.

The non-conductive material is advantageously composed of polyphenylene sulfide. As has already been stated in conjunction with the electrode section that is made to be semiconductive by the carbon component, the polyphenylene sulfide has a coefficient of thermal expansion which corresponds very largely to that of the cast resin. According to the invention, stresses between the holder and the insulating body are thus also prevented.

In contrast to this, the non-conductive material has a mixture of polyphenylene sulfide and glass fibers. The glass fibers reinforce the holder, thus resulting in increased mechanical strength. This makes it possible to avoid destruction or deformation of the coupling electrode, for example during the production process.

The electrode section expediently has a roughened surface. The roughened surface improves the adhesion of the electrode section in the insulating body. This ensures a non-detachable connection between the electrode section and the insulating body, and prevents discharge processes from occurring.

The holder advantageously has a holding ring which is connected to the electrode section.

In one expedient further development in this context, the holding ring is connected to positioning feet, whose free ends form the positioning means.

The component according to the invention has a coupling electrode as described above and can be produced more easily and at a lower cost owing to the simpler positioning of the coupling electrode.

The component is expediently a bushing which allows conductor sections at a high-voltage potential to be passed through a wall to which, for example, ground potential is applied, without this resulting in discharge processes.

In contrast to this, the component is a so-called post insulator whose free ends are on the one hand connected to components at a high-voltage potential and on the other hand are connected to components at ground potential.

The coupling electrode is advantageously completely embedded in the insulating body.

Further expedient refinements and advantages of the invention are the subject matter of the following descriptions of exemplary embodiments with reference to the figures of the drawing, with identical reference symbols referring to identical components, and in which:

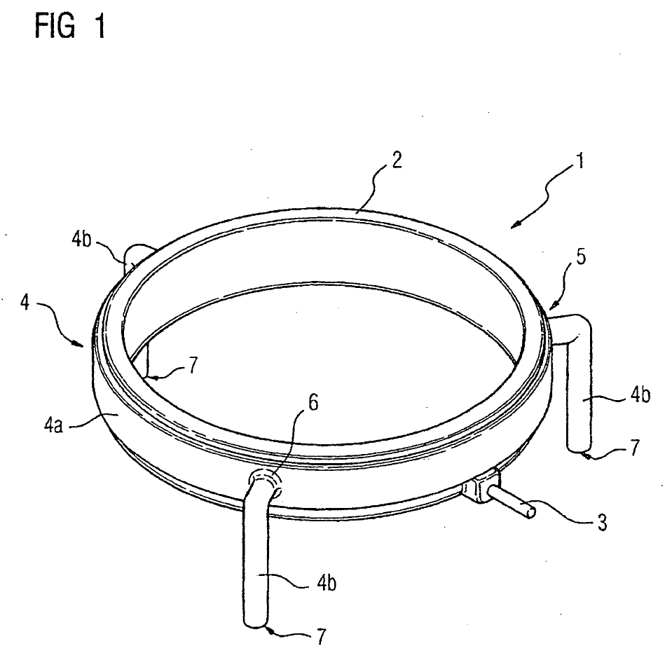

FIG. 1 shows a perspective view of one exemplary embodiment of the coupling electrode according to the invention,

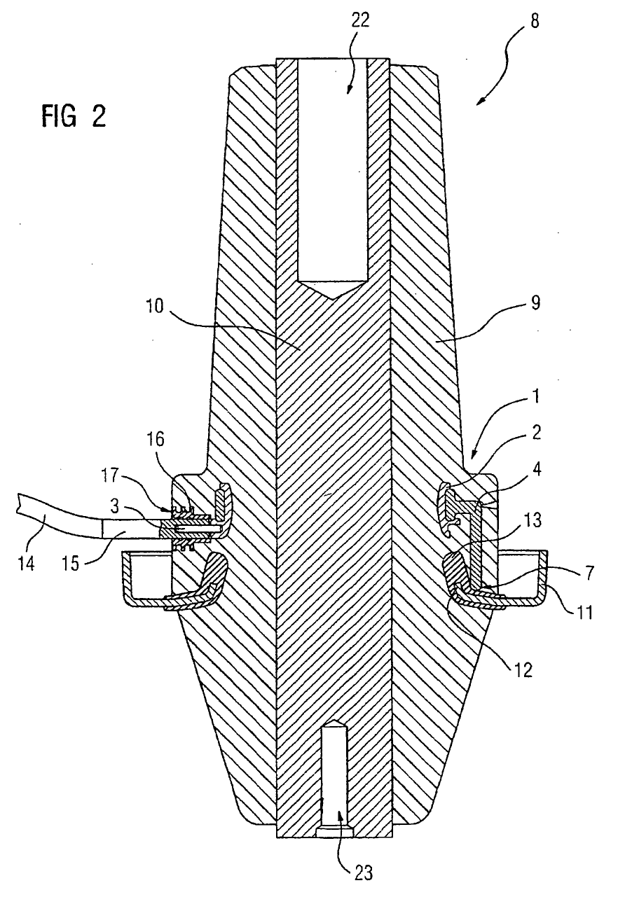

FIG. 2 shows a cross-sectional view through one exemplary embodiment of the component according to the invention,

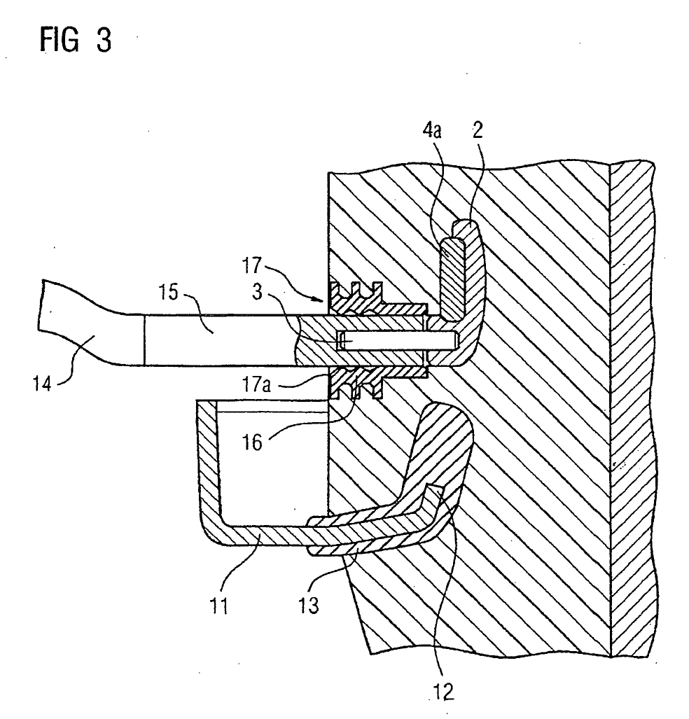

FIG. 3 shows an enlarged illustration of the component shown in FIG. 2 in the form of a cross-sectional view, and

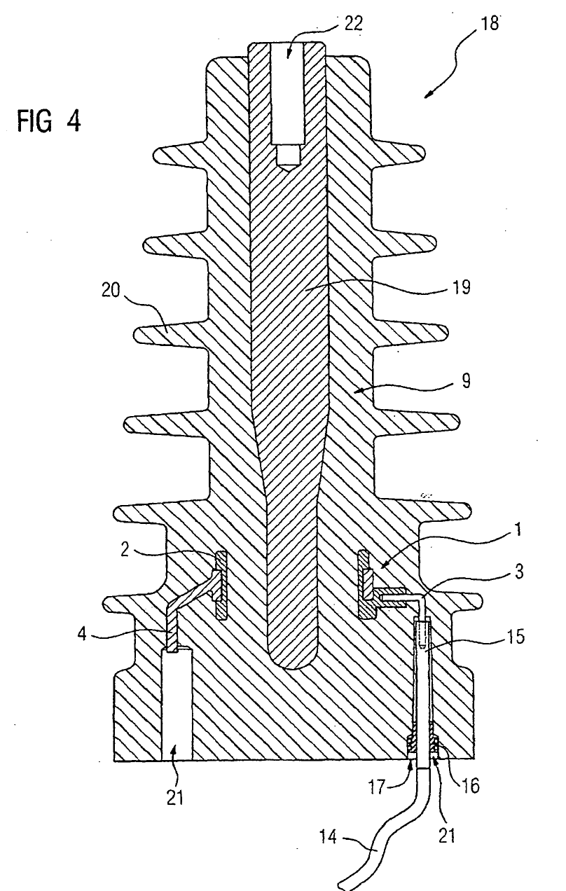

FIG. 4 shows a further exemplary embodiment of the component according to the invention, in the form of a cross-sectional view.

FIG. 1 shows one exemplary embodiment of the coupling electrode 1 according to the invention, illustrated in perspective. The coupling electrode 1 has an annular electrode section 2 as well as a connecting pin 3, which is electrically to it, as a connecting element which, in the example shown in FIG. 1, is attached to the lower ring side of the electrode section 2, and projects outwards from there.

The coupling electrode 1 also has a holder 4, whose attachment side 5 is firmly connected to the electrode section 2. For this purpose, the holder 4 has a holding ring 4a which is clamped to the electrode section and on which three identical L-shaped holding feet 4b are integrally formed. The longer limbs of the L-shaped holding feet 4b of the holder 4 are in the form of free ends, thus forming positioning means 7. The three free ends 7 define a planar positioning surface on which the coupling electrode 1 can be mounted securely and in a stable manner.

Electrode section 2 of the coupling electrode 1 is made of a semiconductive plastic and is in this case made of polyphenylene sulfide with a carbon proportion of 30% by weight. The electrically non-conductive holder 4 is in contrast produced from pure polyphenylene sulfide, which has been mechanically reinforced with glass fibers.

FIGS. 2 and 3 show one exemplary embodiment of a component 8 according to the invention, in the form of a cross-sectional view. The component 8 illustrated here has a rotationally symmetrical insulating body 9 composed of cast resin. A conductor section 10 extends through the insulating body 9 and is equipped with attachment means 11 and 12 at its two free ends. The conductor section can be connected by the attachment means 11, 12 to conductors which are at a high-voltage potential, so that the conductor section 10 is itself at a high-voltage potential during operation.

A flange 13, whose free end 14 extends into the insulating body 9 and is sealed there by an elastic material 15, is used for attachment of the component 8, which in this case is a bushing, in the opening through a housing which is at ground potential. In order to measure the potential on the conductor section 10, the coupling electrode 1 is arranged with its electrode section 2 concentrically around the conductor section 10, and is likewise embedded in the insulating body 9. In this case, the positioning means 7 on the holder 4 are placed on the flange 13. A connecting plug 15, that is connected to a connecting line 14, is provided in order to tap off the potential on the electrode section 2 at the connecting pin 3, with the connecting line 14 and (except for its insertion end which makes contact with the connecting pin 3) the connecting plug 15 also being surrounded in a flexible manner by an insulating material. The connecting plug 15 is held, insulated from the external environment, on the insulating body 9 by sealing means 16 which are made from an elastic and non-conductive material, such as silicone or silicone rubber. The sealing means 16 are pushed into latching grooves, which are formed in a cutout 17, by pushing the connecting plug 15 into the cutout 17 that is formed in the insulating body 9. During this process, the connecting plug 15 is clamped in the cutout 17 by the latched sealing means 16, thus resulting in the connecting plug 15 being held in a robust manner and electrically sealed.

FIG. 3 shows an enlarged illustration of the connecting line 14 with the connecting plug 15 and the sealing means 16. As can be seen from this illustration, the electrode section 2 is clamped on an outer ring section 4a of the holder 4. The connecting pin 3 in the illustrated exemplary embodiment is not formed integrally with the electrode section 2. In fact, the connecting pin 3 is positioned in a push-in opening in the electrode section 2, and is clamped to it. The sealing means 16 in the illustrated exemplary embodiment are in the form of a single elastic silicone element.

Within the scope of the invention, it may also be expedient to cover the outside of the connecting plug 15 with a shrink sleeve even before it is inserted onto the connecting pin 3. This improves the sealing, in conjunction with the sealing means 16. It should also be noted that the sealing means 16 cannot just extend within the cutout 17, but can also be passed out of it.

FIG. 4 shows a further exemplary embodiment of a component according to the invention, with this being a so-called post insulator 18, or in other words an insulating post. The post insulator 18 once again has a conductor section 19, although this does not extend entirely through the insulating body 9 of the post insulator 18 but has a free end which is completely embedded in the insulating body 9. The conductor section 19 also has attachment means 11 for attachment of a conductor, which is not shown but is at a high-voltage potential. At the opposite end of the post insulator 18 to the attachment means 11, this forms a positioning surface on which the post insulator 18 can be attached at a surface which is at ground potential. Discharging shields 20 are used to increase the creepage distance along the outer surface of the post insulator. As can also be seen, the coupling electrode 1 according to the invention is embedded in the insulating body 9. In the illustrated exemplary embodiment, the connecting element 3, which is firmly and electrically conductively connected to the electrode section 2, is not in the form of a pin but is bent at an angle of 90° with its free end projecting into a cutout 21 in the insulating body 9.

The insertion end of the connecting plug 15 is matched to the depth of the cutout 21, thus allowing the potential on the electrode section 2 to be tapped off reliably in this embodiment of the component 18 as well. Once again, a sealing means 16 which can be latched is used for secure attachment of the connecting plug 15 to the insulating body 9, and for electrical sealing of the connecting plug 15, as well as to prevent the ingress of moisture into the cutout 21.

1-15. (canceled)

16. A coupling electrode for capacitive voltage tapping within an insulating body of a component, the component having a conductor section embedded in the insulating body, configured to carry a high-voltage potential, the coupling electrode comprising:
an electrode section composed of a semiconductive plastic;
a connecting element electrically connected to said electrode section and configured to be electrically contacted from outside the insulating body; and
a holder of non-conductive material connected to said electrode section, said holder having positioning devices enabling said electrode section to be supported with insulated mounting.

17. The coupling electrode according to claim 16, which comprises a connecting plug connected to a conductor and configured to be pushed onto said connecting element.

18. The coupling electrode according to claim 17, which comprises a seal for holding said connecting plug in the insulating body.

19. The coupling electrode according to claim 18, wherein said seal is an elastomer seal.

20. The coupling electrode according to claim 18, wherein said seal is configured to be latched in the insulating body.

21. The coupling electrode according to claim 16, wherein said semiconductive material contains polyphenylene sulfide and carbon fibres.

22. The coupling electrode according to claim 21, wherein a proportion of said carbon fibers in said semiconductive material lies between 15% by weight and 35% by weight of a total weight of said semiconductive material.

23. The coupling electrode according to claim 16, wherein said non-conductive material consists essentially of polyphenylene sulfide.

24. The coupling electrode according to claim 16, wherein said non-conductive material comprises a mixture of polyphenylene sulfide and glass fibers.

25. The coupling electrode according to claim 16, wherein said electrode section has a roughened surface.

26. The coupling electrode according to claim 16, wherein said holder includes a holding ring connected to said electrode section.

27. The coupling electrode according to claim 26, wherein said holder further includes positioning feet connected to said holding ring and having free ends forming said positioning devices.

28. A component, comprising:
at least one conductor section configured to carry a high-voltage potential;
an insulating body formed of insulating material and having embedded therein each of said at least one conductor section; and
a coupling electrode according to claim 16 disposed in vicinity of said at least one conductor section for tapping off a voltage of said conductor section.

29. The component according to claim 28, wherein said coupling electrode is completely embedded in said insulating body.

30. The component according to claim 28, wherein said insulating body is formed with latching grooves for latching a seal in said insulating body.
